(19) United States
(12) Patent Application Publication
(10) Pub. No.: US 2008/0105888 A1
(43) Pub. Date: May 8, 2008

(54) LIGHT-EMITTING DIODE PACKAGE STRUCTURE

(75) Inventors: Cheng WANG, Hsinchu (TW); Jin-Shu Huang, Hsinchu (TW); Ching-Po Lee, Hsinchu (TW); Nien-Hui Hsu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CORETRONIC CORPORATION, Hsinchu (TW)

(21) Appl. No.: 11/838,896

(22) Filed: Aug. 15, 2007

(30) Foreign Application Priority Data
Nov. 3, 2006 (TW) 95140667

(51) Int. Cl. H01L 33/00

(52) U.S. Cl. 257/98; 257/E33.059

(57) ABSTRACT

A light-emitting diode (LED) package structure including a lead frame, an LED chip, and a circuit board is provided. The lead frame includes a first lead and a second lead. The LED chip is disposed on the first lead and electrically connected to the first lead and the second lead. The circuit board is disposed on the lead frame and electrically connected to the first lead and the second lead. Moreover, the circuit board and the LED chip are disposed at the same side of the lead frame.

### CROSS-REFERENCE TO RELATED APPLICATION

This application claims the priority benefit of Taiwan application serial no. 95140667, filed Nov. 3, 2006. All disclosure of the Taiwan application is incorporated herein by reference.

### BACKGROUND OF THE INVENTION

1. Field of Invention

The present invention relates to a package structure. More particularly, the present invention relates to a light-emitting diode (LED) package structure.

2. Description of Related Art

Referring to FIG. 1, a conventional LED package structure 100 includes a slug 120, a lead frame 130, an LED chip 140, and a lens 150. The LED chip 140 is adhered onto the slug 120 through an electrically conductive glue 170. Furthermore, the LED chip 140 is electrically connected to a first lead 132 of the lead frame 130 through the electrically conductive glue 170, the slug 120, and a bonding wire 180a, and then electrically connected to a second lead 134 of the lead frame 130 through a bonding wire 180b. The lens 150 covers the LED chip 140. In practical application, the package structure 100 must be used together with a circuit board 110. The circuit board 110 has a circuit layer 112, the slug 120 is adhered onto the circuit layer 112 through a thermal grease 160, and the lead frame 130 is soldered on the circuit layer 112.

Heat generated by the LED chip 140 is transferred to the circuit board 110 through the electrically conductive glue 170, the slug 120, and the thermal grease 160, and then transferred to the outside through the circuit board 110. However, as the heat dissipation path is too long and the attachment between the components is not so satisfactory, the heat dissipation efficiency is relatively poor. If the thermal grease is used to improve the attachment between the components, the heat resistance is increased additionally. Further, if an FR4 printed circuit board with a low cost is used as the circuit board 110, due to having a high heat resistance, the FR4 printed circuit board still does not meet the heat dissipation requirement. Therefore, in order to improve the heat dissipation efficiency, a metal core printed circuit board (MCPCB) must be used. However, the cost of the MCPCB is high, and the manufacturing cost of the package structure is increased accordingly. Furthermore, although the MCPCB is made of thermally conductive metals, such as aluminum, a copper layer (conductive layer) and a dielectric layer are disposed between the aluminum layer and the slug 120. The thermal conductivity coefficient of the dielectric layer is very small and then generates a lot of heat resistance, thereby reducing the heat dissipation efficiency.

When the LED package structure 100 is applied in a light source module, a plurality of LED package structures with different colors is usually bonded onto a strip circuit board, a thermal pad is attached onto the back surface of the circuit board, and then the thermal pad is combined with a heat-dissipating plate or a heat-dissipating sheet, so as to achieve the purpose of lowering the temperature of the LED package structure.

Referring to FIG. 2, another conventional LED package structure 200 comprises a circuit board 210, an LED chip 220, and a lens 230. The circuit board 210 has a circuit layer 212 and the LED chip 220 is adhered onto the circuit layer 212 through an electrically conductive glue 240. The LED chip 220 is electrically connected to a positive circuit of the circuit layer 212 through the electrically conductive glue 240 and then electrically connected to a negative circuit of the circuit layer 212 through a bonding wire 250. The lens 230 covers the LED chip 220.

Heat generated by the LED chip 220 is transferred to the circuit board 210 through the electrically conductive glue 240, and then transferred to the outside through the circuit board 210. However, the LED chip 220 is directly adhered onto the circuit layer 212 and a heat source is not dissipated through the slug 120 in FIG. 1, so that the heat dissipation efficiency is unsatisfactory. Furthermore, if an FR4 printed circuit board with a low cost is used as the circuit board 210, due to having a high heat resistance, the FR4 printed circuit board still does not meet the heat dissipation requirement. Therefore, in order to improve the heat dissipation efficiency, an MCPCB needs to be used. However, the cost of the MCPCB is high, and the manufacturing cost of the package structure 200 is increased accordingly. Similarly, if the LED package structure 200 is applied in a light source module, a thermal pad needs to be combined with a heat-dissipating plate or a heat-dissipating sheet, so as to achieve the purpose of reducing the temperature of the LED package structure.

### SUMMARY OF THE INVENTION

Accordingly, the present invention is related to an LED package structure to improve heat dissipation efficiency.

In order to achieve the aforementioned and other advantages, the present invention provides an LED package structure, which comprises a lead frame, an LED chip, and a circuit board. The lead frame comprises a first lead and a second lead. The LED chip is disposed on the first lead and electrically connected to the first lead and the second lead. The circuit board is disposed on the lead frame and electrically connected to the first lead and the second lead. Furthermore, the circuit board and the LED chip are disposed at the same side of the lead frame.

In the present invention, the LED chip is disposed on the first lead, such that heat generated by the LED chip is transferred to the outside through the first lead. Since the heat dissipation path is short and the heat resistance is greatly reduced, the LED package structure provided by the present invention has high heat dissipation efficiency.

Other objectives, features and advantages of the present invention will be further understood from the further technology features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of the conventional LED package structure.

FIG. 2 is a schematic view of the conventional LED package structure.

FIG. 3A is a top view of the LED package structure according to an embodiment of the present invention.

FIG. 3B is a schematic sectional view taken along Line I-I′ in FIG. 3A.

FIG. 4 is a top view of the lead frame according to an embodiment of the present invention.

FIG. 5 is a schematic view of the LED package structure according to another embodiment of the present invention.

FIG. 6 is a schematic view of the LED package structure according to still another embodiment of the present invention.

FIGS. 7A and 7B are top views of the LED package structures in yet another two embodiments of the present invention.

### DESCRIPTION OF EMBODIMENTS

It is to be understood that other embodiments may be utilized and structural changes may be made without departing from the scope of the present invention. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” and “coupled,” and variations thereof herein are used broadly and encompass direct and indirect connections, couplings, and mountings.

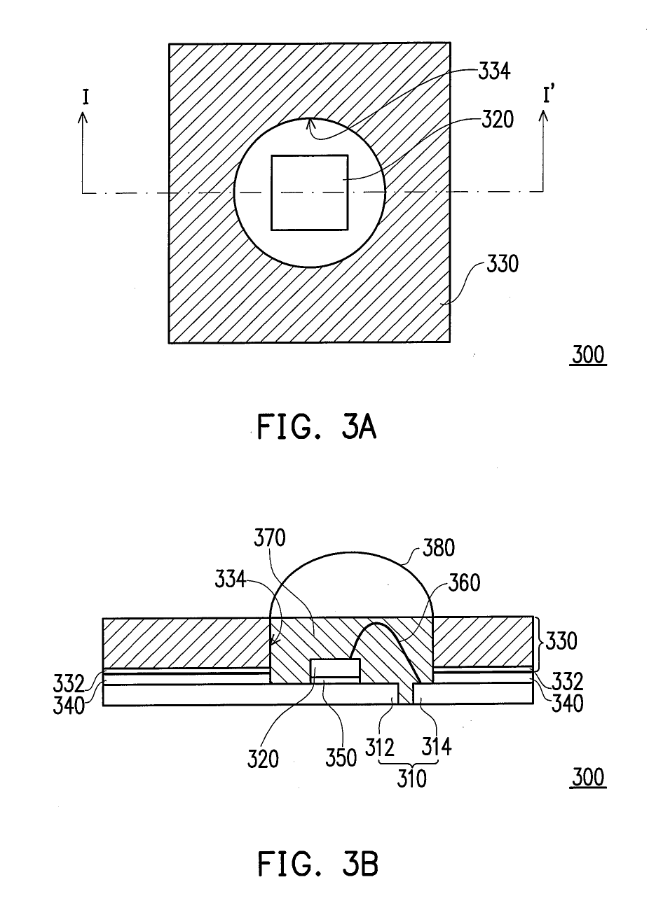

Referring to FIGS. 3A and 3B, the LED package structure 300 in this embodiment includes a lead frame 310, an LED chip 320, and a circuit board 330. The lead frame 310 includes a first lead 312 and a second lead 314, wherein the surface area of the first lead 312 is larger than that of the second lead 314. The LED chip 320 is disposed on the first lead 312 and electrically connected to the first lead 312 and the second lead 314. An electrically conductive adhesive layer 350 is disposed between the LED chip 320 and the first lead 312, such that the LED chip 320 is electrically connected to the first lead 312. The electrically conductive adhesive layer 350 is, for example, the electrically conductive glue. Two ends of a bonding wire 360 are connected to the LED chip 320 and the second lead 314 respectively, such that the LED chip 320 is electrically connected to the second lead 314. The bonding wire 360 is, for example, a gold wire.

The circuit board 330 is disposed on the lead frame 310 and electrically connected to the first lead 312 and the second lead 314. The circuit board 330 and the LED chip 320 are disposed at the same side of the lead frame 310. A solder layer 340 is disposed between the circuit board 330 and the lead frame 310, such that the circuit board 330 is connected to the lead frame 310. Furthermore, the circuit board 330 has a circuit layer 332 facing the lead frame 310, and the circuit layer 332 includes a positive circuit and a negative circuit.

The LED chip 320 is electrically connected to the positive circuit of the circuit layer 332 through the electrically conductive adhesive layer 350, the first lead 312, and a portion of the solder layer 340 between the first lead 312 and the circuit board 330, and then electrically connected to the negative circuit of the circuit layer 332 through the bonding wire 360, the second lead 314, and another portion of the solder layer 340 between the second lead 314 and the circuit board 330.

The circuit board 330 has an opening 334 in which the LED chip 320 is disposed. Furthermore, the LED package structure 300 further includes an encapsulant 370 which is filled in the opening 334 of the circuit board 330 and a gap between the first lead 312 and the second lead 314, and covers the LED chip 320 to protect the LED chip 320. The encapsulant 370 is, for example, a transparent encapsulant, such that the light emitted from the LED chip 320 passes through. Additionally, in this embodiment, an external surface of the encapsulant 370 above the LED chip 320 forms a lens surface, or a lens 380 is disposed on the encapsulant 370, so as to adjust the radiation pattern of the LED package structure 300 and enhance the light output efficiency.

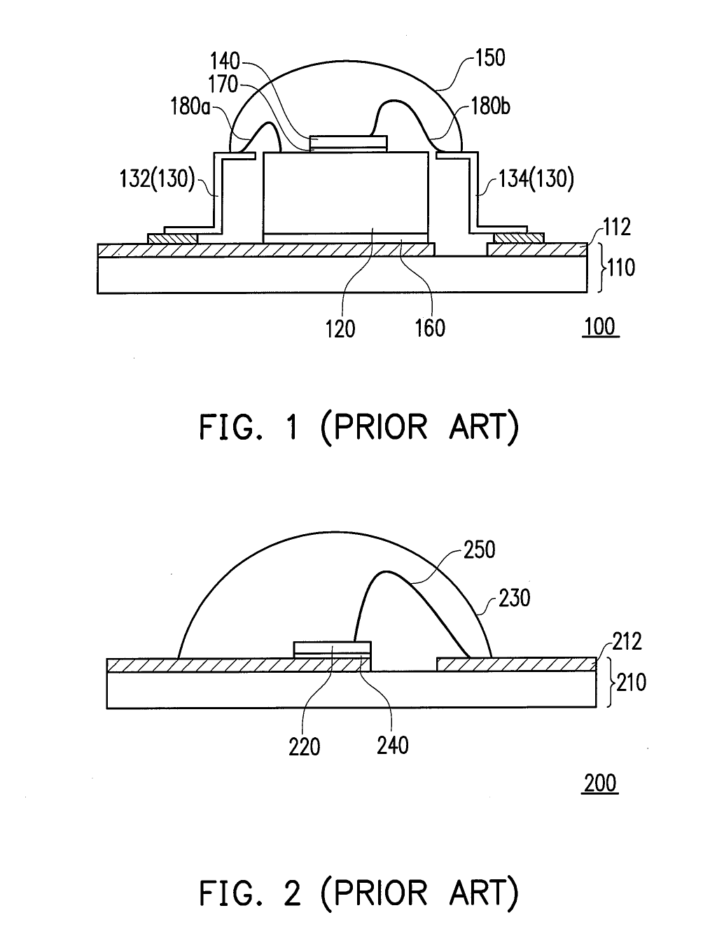

In this embodiment, since the LED chip 320 is directly adhered onto the first lead 312 through the electrically conductive adhesive layer 350 and the first lead 312 is in direct contact with the outside, heat generated by the LED chip 320 is directly transferred to the outside through the first lead 312 after being transferred to the first lead 312 through the electrically conductive adhesive layer 350. In other words, the LED package structure 300 has a short heat dissipation path, thus having optimal heat dissipation efficiency. Furthermore, the first lead 312 in the LED package structure 300 spread the heat generated by the LED chip 320 in the absence of the slug 120 (as shown in FIG. 1), so the manufacturing cost is saved and the thickness of the LED package structure 300 is reduced. Additionally, in this embodiment, the thermal grease is not required to increase the attachment between the components, thereby reducing the heat resistance of the components, so the time cost and material cost of coating the thermal grease are saved. Furthermore, since the heat dissipation path does not pass the circuit board 330, the circuit board 330 is a printed circuit board (such as an FR4 printed circuit board) made of a low heat conductive material, thus reducing the manufacturing cost without affecting the heat dissipation efficiency of the LED package structure 300.

Since the LED package structure 300 does not have the conventional slug 120, the size of the opening 334 of the circuit board 330 need not to be changed according to the size of the slug 120, and the size of the opening 334 only needs to ensure that the light emitted by the LED chip 320 will not be shielded.

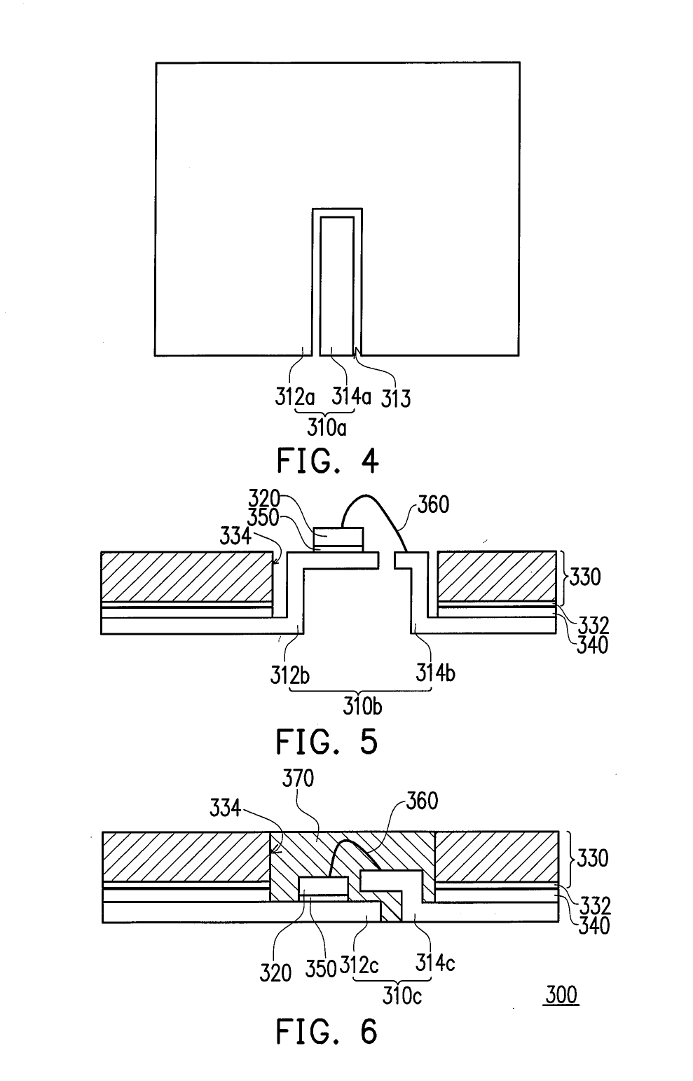

It is worthy to mention that different from the conventional strip lead frame, the shape of the lead frame of the LED package structure 300 in this embodiment is designed in accordance with various design requirements. For example, in the lead frame 310a (as shown in FIG. 4), the first lead 312a with the heat dissipation function is designed to be a sheet with a larger dissipation area and has an indentation 313. The second lead 314a without the heat dissipation function is designed to be strip-shaped and is disposed in the indentation 313. The first lead 312a has a larger dissipation area, thereby helping to improve the heat dissipation efficiency of the entire LED package structure 300.

Additionally, a heat sink (not shown) is disposed on a surface of the lead frame 310 other than the surface of the lead frame 310 on which the LED chip 320 is disposed, and a thermal pad is disposed between the heat sink and the lead frame 310, so as to transfer the heat generated by the LED chip 320 to the outside of the LED package structure 300 through the thermal pad and the heat sink.

Referring to FIG. 5, in order to avoid that the light emitted by the LED chip 320 is shielded by the side walls of the opening 334 and does not be outputted, a first lead 312b and a second lead 314b of a lead frame 310b extend through the opening 334 from one side of the circuit board 330 towards the other side of the circuit board 330, and the LED chip 320 is disposed on a portion of the first lead 312b substantially on the surface of the circuit board 330. In this embodiment, since the LED chip 320 is disposed above the opening 334, the light emitted by the LED chip 320 will not be shielded by the side walls of the opening 334.

In order to prevent water vapor from directly entering the package structure via the gap between the first lead and the second lead and then affecting the reliability of the package structure, in a lead frame 310c in FIG. 6, a second lead 314c extends to above a portion of a first lead 312c. In this manner, when water vapor enters the package structure via the gap between the first lead 312c and the second lead 314c, it will be firstly blocked by the portion of the second lead 314c extending to the above of the first lead 312c, thereby improving the reliability of the package structure.

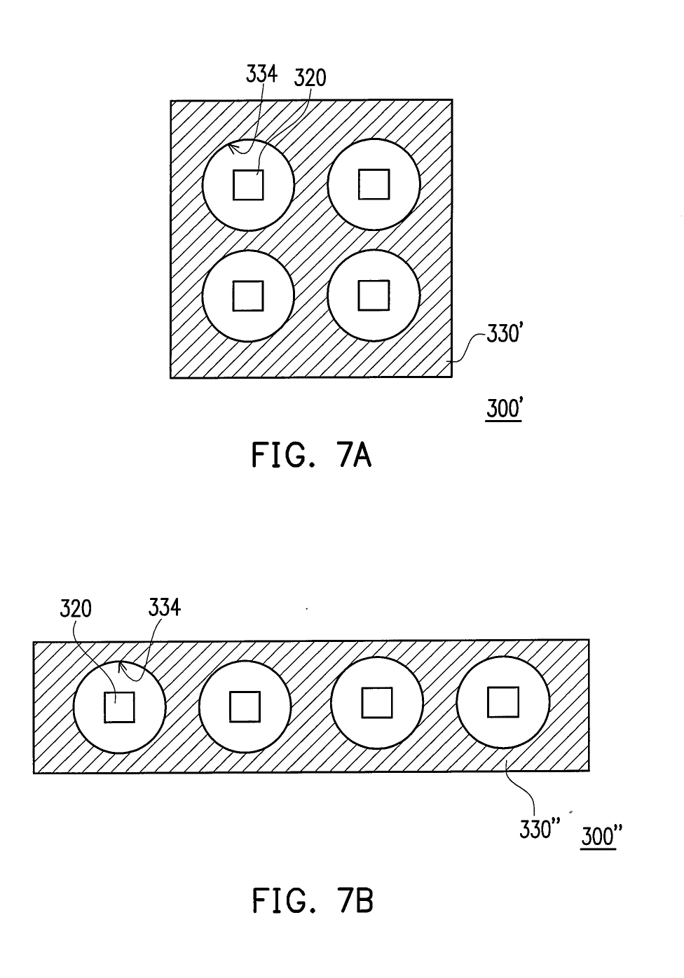

It should be noted that although the aforementioned package structures are all a single-chip LED package structure, the package structure in the present invention is also a multi-chip LED package structure. The multi-chip LED package structure is a combination of a plurality of the aforementioned single-chip LED package structures, but each of the LED chips is electrically connected to the same circuit board. Furthermore, the shape of the circuit board is adjusted as required. For example, the circuit board is a rectangular circuit board (such as a circuit board 330′ of an LED package structure 300′ in FIG. 7), and in the LED package structure 300′, the LED chips 320 are arranged in an array. Furthermore, the circuit board is also a strip circuit board (such as a circuit board 330″ in an LED package structure 300″ in FIG. 7B), and in the LED package structure 300″, the LED chips 320 are arranged in the extension direction of the circuit board 330″. In addition, in FIGS. 7A and 7B, the colors of the lights emitted from the LED chips 320 is all the same, partially the same, or all different. When the colors of the lights emitted from the LED chips 320 are different, the lead frames 312 must be separated from each other.

In view of the above, the package structure of the present invention has at least the following advantages.

1. In the present invention, the heat generated by the LED chip is directly transferred to the outside through the first lead, and thus the package structure has optimal heat dissipation efficiency. Furthermore, the size of the first lead is not limited by the size of the opening of the circuit board and is adjusted according to the heat generation amount of the LED chip.

2. In the present invention, the slug in the conventional art is not required, so the manufacturing cost is reduced and the thickness of the package structure is reduced.

3. Since the heat dissipation path does not pass the circuit board, the heat dissipation efficiency of the package structure will not be affected even if a circuit board with a low cost is employed.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A light-emitting diode package structure, comprising:
a lead frame, comprising a first lead and a second lead;
a light-emitting diode chip, disposed on the first lead and electrically connected to the first lead and the second lead; and
a circuit board, disposed on the lead frame and electrically connected to the first lead and the second lead, wherein the circuit board and the light-emitting diode chip are disposed at the same side of the lead frame.

2. The light-emitting diode package structure as claimed in claim 1, wherein the circuit board has a circuit layer facing the lead frame.

3. The light-emitting diode package structure as claimed in claim 1, further comprising a bonding wire and an electrically conductive adhesive layer, wherein two ends of the bonding wire are connected to the light-emitting diode chip and the second lead respectively, and the electrically conductive adhesive layer is disposed between the light-emitting diode chip and the first lead.

4. The light-emitting diode package structure as claimed in claim 1, wherein the circuit board has an opening, wherein the first lead and the second lead extend through the opening from one side of the circuit board towards the other side, and the light-emitting diode chip is disposed on a portion of the first lead on the other side of the circuit board.

5. The light-emitting diode package structure as claimed in claim 1, wherein the surface area of the first lead is larger than that of the second lead.

6. The light-emitting diode package structure as claimed in claim 1, wherein the circuit board has an opening in which the light-emitting diode chip is disposed.

7. The light-emitting diode package structure as claimed in claim 6, further comprising an encapsulant which is filled in the opening of the circuit board and a gap between the first lead and the second lead and covers the light-emitting diode chip.

8. The light-emitting diode package structure as claimed in claim 7, wherein an external surface of the encapsulant above the light-emitting diode chip forms a lens surface.

9. The light-emitting diode package structure as claimed in claim 7, further comprising a lens disposed on the encapsulant.

10. The light-emitting diode package structure as claimed in claim 1, further comprising a solder layer disposed between the lead frame and the circuit board.

11. The light-emitting diode package structure as claimed in claim 1, further comprising a heat sink and a thermal pad, wherein the heat sink is disposed on a surface of the lead frame other than the surface of the lead frame on which the light-emitting diode chip is disposed, and the thermal pad is disposed between the heat sink and the lead frame.
